(19) United States
(12) Patent Application Publication
(10) Pub. No.: US 2025/0211256 A1
(43) Pub. Date: Jun. 26, 2025

(54) DISCRETIZED SOFT-INFORMATION FOR GUESSING RANDOM ADDITIVE NOISE DECODING

(71) Applicants: Massachusetts Institute of Technology, Cambridge, MA (US); National University of Ireland Maynooth, Maynooth (IE)

(72) Inventors: Muriel MEDARD, Belmont, MA (US); Kenneth R. DUFFY, Belmont, MA (US); Evan P. GABHART, Cambridge, MA (US)

(73) Assignees: Massachusetts Institute of Technology, Cambridge, MA (US); National University of Ireland Maynooth, Maynooth (IE)

(21) Appl. No.: 18/848,336

(22) PCT Filed: Jan. 24, 2023
(86) PCT No.: PCT/US2023/061153

§ 371 Date: Sep. 18, 2024

Related U.S. Application Data
(60) Provisional application No. 63/323,180, filed on Mar. 24, 2022.

(51) Int. Cl. H03M 13/45; H03M 13/37

(52) U.S. Cl. CPC H03M 13/451; H03M 13/3746

(57) ABSTRACT

We disclose a soft-detection variant of Guessing Random Additive Noise Decoding (GRAND) called discretized soft-information for GRAND (DSGRAND) that can efficiently decode any moderate redundancy block-code in an algorithm that is suitable for highly parallelized implementation in hardware. DSGRAND provides near maximum likelihood decoding performance when provided with five or more bits of soft information per received bit, by discretizing the soft information into noise effect sequences and allocating those sequences into bins according to weight. The use of these bins provides a separate, simplified manner of sequencing noise guessing.

### STATEMENT REGARDING FEDERALLY SPONSORED RESEARCH

This invention was made with government support under HR0011-2-12-0008 awarded by the Defense Advanced Research Projects Agency. The government has certain rights in the invention.

### BACKGROUND

As Maximum Likelihood (ML) error correcting decoding of linear codes is NP-complete, the engineering paradigm has been to co-design restricted classes of linear code-books with code-specific decoding methods that exploit the code-structure to enable computationally efficient approximate-ML decoding. For example, Bose-Chaudhuri-Hocquenghem (BCH) codes with hard detection Berlekamp-Massey decoding, Low Density Parity Check codes and belief propagation, CRC-Assisted Polar (CA-Polar) codes, which have been selected for all control channel communications in 5G New Radio (NR), and CRC-Assisted Successive Cancellation List (CA-SCL) decoding.

Modern applications, including augmented and virtual reality, vehicle-to-vehicle communications, the Internet of Things, and machine-type communications, have driven demand for Ultra-Reliable Low-Latency Communication (URLLC). To enable these technologies requires the use of short, high-rate codes, reviving the possibility of creating high accuracy universal decoders that are suitable for hardware implementation. Accurate, practically realizable universal decoders offer the possibility of reduced hardware footprint, the provision of hard- or soft-detection decoding for codes that currently only have one class of decoder, and future-proofing devices against the introduction of new codes.

### SUMMARY OF DISCLOSED EMBODIMENTS

Guessing Random Additive Noise Decoding (GRAND) is a recently introduced universal decoder that was originally established for hard decision demodulation systems; see U.S. Pat. Nos. 10,608,673 and 11,095,314. GRAND algorithms operate by sequentially removing putative noise-effects from the demodulated received sequence and querying if what remains is in the code-book. The first instance where a code-book member is found is the decoding. Pseudo-code for GRAND can be found in Table 1 below, as reproduced in the flowchart of FIG. 1. If GRAND queries binary noise effects from most likely to least likely based on available hard or soft information, it can be readily established that it identifies ML decodings. In the hard detection setting, GRAND lends itself to mathematical analysis and can be used to determine error exponents for a broad class of additive noise models.

TABLE 1

```
Pseudocode for GRAND algorithms.
Inputs: Code-book membership function C : {0,1}ⁿ [symbol]
{0,1}; demodulated bits yⁿ; optional information Φ.
Output: Decoding C*^{,n}.
d ← 0, D ← 0.
while d=0 do
  zⁿ ← next most likely binary noise effect sequence
  (which may depend on Φ)
  D ← D + 1
  if C(yⁿ ⊖zⁿ) = 1 then
    c*^{,n} ← yⁿ ⊖ zⁿ
    d ← 1
    return c*^{,n}.
  end if
end while
```

For an [n,k] code, where k information bits are transformed into n coded bits for communication, GRAND algorithms (i.e. algorithms implemented in accordance with the GRAND concepts) in a binary symmetric channel will identify an erroneous decoding after approximately geometrically distributed number of code-book queries with mean 2^{n-k} and correctly decode if they identify a code-word beforehand. As a result, an upper bound on the complexity of GRAND algorithms is determined by the number of redundant bits rather than the code length or rate directly, rendering them suitable to decode any moderate redundancy code of any length. The performance difference among GRAND variants stems generally from their utilization of statistical noise models or soft information to improve the targeting of their queries prior to the identification of an erroneous decoding.

The evident parallelizability of hard detection GRAND's code-book queries have already resulted in the proposal and realization of efficient circuit implementations for binary symmetric channels. An algorithm has also been introduced for channels subject to bursty noise whose statistics are known to the receiver, which has also resulted in proposed circuit implementations.

In accordance with the concepts described herein, it has been recognized that one question is how to make use of soft detection information, when it is available, in order to change, adjust, modify or otherwise alter (and ideally improve) GRAND's query order. Several techniques have been proposed to make use of soft detection information. One technique, referred to as Symbol Reliability GRAND (SRGRAND), avails of the most limited quantized soft information where one additional bit tags each demodulated symbol as being reliably or unreliably received. SRGRAND is mathematically analyzable, implementable in hardware, and provides a 0.5-0.75 dB gain over hard-detection GRAND. One technique, referred to as Soft GRAND (SGRAND), uses real-valued soft information per demodulated bit to build a bespoke noise-effect query order for each received signal. Using dynamic max-heap data structures, it is possible to create a semi-parallelizable implementation in software and it provides a benchmark for optimal decoding accuracy performance, but its execution is less amenable to hardware implementation.

A technique referred to as Ordered Reliability Bits GRAND (ORBGRAND) aims to bridge the gap between SRGRAND and SGRAND by obtaining the decoding accuracy of the latter in an algorithm that is suitable for implementation in circuits. See U.S. Patent Publication 2002/0302931. For a block code of length n, the ORBGRAND technique uses up to [log₂(n)] bits of code-book-independent quantized soft detection information per received bit, the rank-order of each bit's reliability, to determine an accurate decoding. It retains the hard-detection algorithm's suitability for a highly parallelized implementation in hardware, and high throughput VLSI designs have already been proposed. ORBGRAND provides near-ML decodings for block error rates greater than 10⁻⁴, but is less precise at higher SNR as ORBGRAND's noise effect query order diverges from the optimal rank order. An engineering approach to improve ORBRGRAND's performance at higher SNR has been proposed.

As new applications drive demand for shorter, higher rate error correcting codes, computationally efficient universal decoding becomes a possibility. Universal decoders have many practical benefits, including the ability to support a practical infinity of distinct codes with the one efficient piece of software or hardware, enabling the best choice of code for each application and future proofing devices to the introduction of new codes.

Even though it was only recently introduced, GRAND is one promising approach to realizing this possibility. Hard detection GRAND algorithms enable accurate decoding of codes, such as CA-Polar codes, for which there is only a dedicated soft detection decoder. Moreover, they upgrade codes for which there are only hard detection decoders, such as BCH codes, or no error correcting decoder at all, such as CRCs, to soft detection decoding. Much of the existing literature reporting results from GRAND algorithms, both hard and soft detection, has shown that the decoding performance is largely driven by the quality of the decoder rather than the code, and that good CRCs and codes selected at random offer as good performance as highly structured codes.

As noted above, one soft detection version of GRAND that has been demonstrated to be suitable for hardware implementation is ORBGRAND. Described herein is an alternative variant of GRAND referred to as discretized soft-information for GRAND (or “DSGRAND”). The DSGRAND technique utilizes distinctly quantized soft detection information. It can tailor its levels of quantization to application need, providing improved block error rate performance as quantization becomes finer, which corresponds to more bits of soft information. DSGRAND inherits all the desirable features of GRAND algorithms, including universality, parallelizability and reduced algorithmic effort as SNR increases. DSGRAND has increasingly accurate performance as the number of soft information bits per received bit increases. With five or more soft bits per bit, it provides comparable block error rate performance to ORBGRAND in an algorithmically distinct package that is also suitable for hardware implementation.

Thus, a first embodiment of the concepts, techniques, and structures disclosed herein is a method of decoding a plurality of received symbols. The method includes further receiving, for one or more of the received symbols, up to log₂(Q) bits of associated soft information, where log₂(Q) is an integer. The method also includes assigning, to at least one of the one or more of the received symbols, one or more noise effect symbols having a respective weight that is determined by the up to log₂(Q) bits of associated soft information. The method next includes forming noise effect sequences from the noise effect symbols. The method then includes determining a noise effect sequence guessing order according to the respective weights. The method requires forming one or more words by inverting a set of sequences of noise effect symbols, on the plurality of received symbols, according to the noise effect sequence guessing order. The method then requires determining whether each of the formed one or more words is a codeword. The method concludes by terminating according to a termination condition.

In some embodiments, determining the noise effect sequence guessing order comprises determining a total weight of each noise effect sequence and allocating the noise effect sequences into bins according to their respective total weights.

In some embodiments, allocating the noise effect sequences into bins comprises allocating noise effect sequences having larger reliability values to bins having smaller total weights.

In some embodiments, allocating a noise effect sequence into a given bin comprises solving an integer partition problem associated with the total weight of the given bin.

Some embodiments further include determining, for one or more of the noise effect symbols, one of up to Q reliability levels by discretizing a reliability value for the one or more of the noise effect symbols.

In some embodiments, the received symbols are binary symbols and each of the one or more of the received symbols has one noise effect symbol.

In some embodiments, the selection of noise effect symbols in a particular noise effect sequence is determined by a measure of proximity of the noise effect sequence to the received signal.

In some embodiments, the measure of proximity comprises a Hamming weight.

Another embodiment is a system for decoding a plurality of received symbols. The system includes a receiver for receiving from a data channel the plurality of received symbols and further receiving, for one or more of the received symbols, up to log₂(Q) bits of associated soft information, where log₂(Q) is an integer. The system also includes a discretization system for assigning, to at least one of the one or more of the received symbols, one or more noise effect symbols having a respective weight that is determined by the up to log₂(Q) bits of associated soft information, and for forming noise effect sequences from the noise effect symbols. The system also has a noise guesser for iteratively guessing noise effect sequences according to a noise effect sequence guessing order determined according to the respective weights. And the system has a putative codeword buffer for transiently storing putative codewords formed by inverting a set of sequences of noise effect symbols, on the plurality of received symbols, according to the noise effect sequence guessing order. The system further includes a codeword validator for determining whether each of the formed one or more words is a codeword.

In some embodiments, the receiver comprises a network interface card.

In some embodiments, the putative codeword buffer comprises a primary storage or a volatile memory.

Some embodiments further have a codebook for use by the codeword validator to determine whether the word stored in the putative codeword buffer is a valid codeword.

Some embodiments have a noise outputter for outputting channel noise effect sequences, as determined by the codeword validator.

In some embodiments, the noise guesser is configured to determine the noise effect sequence guessing order by determining a total weight of each noise effect sequence assigned by the discretization system and allocating the noise effect sequences into bins according to their respective total weights.

In some embodiments, allocating the noise effect sequences into bins comprises allocating noise effect sequences having larger reliability values to bins having smaller total weights.

In some embodiments, allocating a noise effect sequence into a given bin comprises solving an integer partition problem associated with the total weight of the given bin.

In some embodiments, the discretization system is configured to determine, for one or more of the noise effect symbols, one of up to Q reliability levels by discretizing a reliability value for the one or more of the noise effect symbols.

In some embodiments, the receiver is configured to receive the received symbols as binary symbols.

In some embodiments, the discretization system forms noise effect symbols into a particular noise effect sequence using a measure of proximity of the noise effect sequence to the received signal.

In some embodiments, the measure of proximity comprises a Hamming weight.

### DESCRIPTION OF THE SEVERAL VIEWS OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, embodiments are illustrated by way of example and not limitation in the figures, in which:

FIG. 1 shows an algorithm for Guessing Random Additive Noise Decoding (GRAND);

FIG. 2 is a block diagram of a communications system having a receiving system with a receiver, a binning (or discretization) system, and a decoder in accordance with an embodiment of the concepts, techniques, devices and systems disclosed herein;

FIG. 3A is a block diagram of an illustrative receiving system which utilizes the guessing techniques described herein;

FIG. 3B is a block diagram of an alternative embodiment of an illustrative receiving system which utilizes the guessing techniques described herein;

FIG. 4 is a flowchart of a method of decoding received symbols according to an embodiment;

FIG. 4A is a flowchart of a method of decoding received symbols according to an alternate embodiment;

FIG. 5 is a plot of block error rate (BLER) vs signal-to-noise ratio per bit (Eb/N0) for decoding a rate 0.97 BCH [255,247] code in a binary phase-shift keyed (BPSK) channel experiencing additive white Gaussian noise (AWGN), using GRAND, ORBGRAND, and embodiments disclosed herein of DSGRAND with varying levels of quantized soft information;

FIG. 6 is a plot of BLER vs Eb/NO for a rate 0.91 CA-Polar [128, 116] code in an AWGN BPSK channel;

FIG. 7 is a plot of BLER vs Eb/NO for a rate 0.98 CA-Polar [512, 500] code in an AWGN BPSK channel;

FIG. 8(a) is a plot of per-bit, real-valued soft information vs received bit sequence number in an illustrative simulation;

FIG. 8(b) is a plot of demodulation of the soft information in FIG. 8(a) into single bits according to GRAND;

FIG. 8(c) is a plot of the absolute value of the real-valued soft information of FIG. 8(a), which is a measure of the reliability of the received bit;

FIG. 9(a) repeats FIG. 8(c) for visual comparison with FIGS. 9(b)-9(d) to emphasize that the real-valued reliability values are unquantized (i.e. take values in a continuum);

FIG. 9(b) shows a 1-bit quantization of the reliability values of FIG. 9(a) according to an embodiment of DSGRAND, in which the continuum is quantized into ranges and reliability values that fall into each range are assigned a respective quantization level (i.e. 1 or 2);

FIG. 9(c) shows a 2-bit quantization of the reliability values of FIG. 9(a) according to an embodiment of DSGRAND, in which the continuum is quantized into ranges and reliability values that fall into each range are assigned a respective quantization level (i.e. 1 through 4);

FIG. 9(d) shows a 3-bit quantization of the reliability values of FIG. 9(a) according to an embodiment of DSGRAND, in which the continuum is quantized into ranges and reliability values that fall into each range are assigned a respective quantization level (i.e. 1 through 8);

FIG. 10(a) repeats FIG. 9(a) for visual comparison with FIGS. 10(b)-10(d);

FIG. 10(b) shows a 1-bit quantization of the reliability values of FIG. 10(a) according to an embodiment of DSGRAND in which reliability thresholds used for quantization are chosen so that each range has a width that is a multiple of a base reliability value;

FIG. 10(c) shows a 2-bit quantization of the reliability values of FIG. 10(a) according to an embodiment of DSGRAND in which reliability thresholds used for quantization are chosen so that each range has a width that is a multiple of a base reliability value;

FIG. 10(d) shows a 3-bit quantization of the reliability values of FIG. 10(a) according to an embodiment of DSGRAND in which reliability thresholds used for quantization are chosen so that each range has a width that is a multiple of a base reliability value; and

FIG. 11 shows Hamming weights of guessed noise vs position in the noise effect guessing order for a sequence of 16 batches of noise effect guesses in an embodiment of DSGRAND having 1-bit quantization (i.e. two ranges of per-bit reliability), e.g. as shown in FIG. 9(b).

### DETAILED DESCRIPTION

Before describing the broad concepts, devices, systems and techniques sought to be protected herein, some introductory concepts are explained.

In many systems, particularly in communication systems where a channel comprises one or more communication channels, there may be information available regarding the characteristics of the one or more channels. Such characteristics sometimes effect information (e.g., analog and/or digital signals) propagating in the channel (with such effects referred to herein as “channel effects”). Information about the channel effects (i.e., information describing the channel effects) may include: (1) information related to the general nature of the noise; and/or (2) information related to the specific realization of the noise on the channel.

With respect to information related to a specific realization of the noise affecting the channel, this is may be referred to as “soft information.” Soft information can comprise instantaneous information. For example, soft information can comprise instantaneous detection confidence information, log-likelihood ratio (discussed later), signal-to-noise ratio information, signal-to-interference ratio information, information regarding inter-symbol information (e.g. from a Rake receiver), information about possible noise behaviors (e.g. having noise being more likely at the end of a transmission, when timing information may be stale or approaching obsolescence), or the interplay between modulation (e.g., particular types of modulation) and physical channel.

Such soft information is difficult to account for in decoding schemes. While so-called “Turbo” decoding maintains certain soft information implicitly in its decoding process, other schemes generally require bespoke modifications that add significant complexity. Thus, as for the general behavior of the noise, notwithstanding the development of theoretical improvements, current decoding schemes in general ignore the effect of soft information.

In one embodiment of the concepts, devices, systems and techniques disclosed herein, consider a system using a binary [n,k] block code. Binary data are modulated as symbols, transmitted, and subject to additive continuous noise. The modulated channel output Yⁿ is then demodulated to provide the hard-detection output

yⁿ=demod(Yⁿ)∈ [symbol] ₂ⁿ.

In contrast to the continuous noise impacting the channel, the “noise effect” is the binary difference between the code-word and demodulated output in

$${Z}^{n} = {c}^{n} - demod ( {Y}^{n} ) = {c}^{n} - {y}^{n} ∈ {𝔽}_{2}^{n} .$$

Processing techniques (or generally “algorithms”) based upon the GRAND concepts seek to identify the noise effect, Zⁿ, by rank ordering noise effects, zⁿ, from most likely to least likely based on the information available to them, and querying if what remains when a putative noise effect is removed from a demodulated signal is in the code-book. Thus, for the case of binary symbols, let

$$L ( Y ) = \vert LLR ( Y ) \vert = \vert log ( \frac{P ( Y \vert c = 1 )}{P ( Y \vert c = 0 )} ) \vert$$

denote the reliability of the signal Y, where LLR denotes the log-likelihood ratio. Given L(Y), elementary manipulation reveals that the likelihood that the corresponding hard demodulated bit, y, is in error is

$$B ( Y ) = \frac{{e}^{- L ( Y )}}{1 + {e}^{- L ( Y )}}$$

and so

$$P ( {Z}^{n} = {z}^{n} ) = {\prod }_{i = 1}^{n} ( 1 - B ( {Y}_{i} ) ) {\prod }_{i : {z}_{i} = 1} \frac{B ( {Y}_{i} )}{1 - B ( {Y}_{i} )} ∝ {\prod }_{i : {z}_{i} = 1} \frac{B ( {Y}_{i} )}{1 - B ( {Y}_{i} )} = exp ( - {\sum }_{i = 1}^{n} L ( {Y}_{i} ) {z}_{i} ) .$$

Consequently, to create binary noise effect sequences, zⁿ, rank-ordered by likelihood, it suffices to create them by increasing ϵᵢ₌₁ⁿL(Yᵢ)zᵢ. Distinct GRAND algorithms use different approximations, R(Yᵢ), to L(Yᵢ) that depends on the information that is available to them.

In the absence of soft detection information, the approximation is that R(Yᵢ) is a constant for all i and so noise effect sequences are rank ordered by their Hamming weight, w_{H}(zⁿ)=∈ᵢ₌₁ⁿᵢ. SRGRAND's binary quantization sets R (Yᵢ)=∞ for bits above a threshold, tagging them as being perfectly reliable, and R(Yᵢ) to a constant for those below the threshold, resulting in noise effect sequences following increasing Hamming weight within the region of unreliable bits. ORBGRAND considers the received bits rank-ordered in increasing reliability. If rank ordered reliabilities are increasing linearly, i.e., R(Yᵢ)=αi with any slope α>0, then noise effect sequences follow increasing logistic weight w_{L}(zⁿ)=∈ᵢ₌₁ⁿzᵢ with positions labelled in that rank order. SGRAND makes no approximation, assumes that the L(Yᵢ) are real-valued, and dynamically creates putative noise effect sequences with increasing ∈ᵢ₌₁ⁿL(Yᵢ)zᵢ.

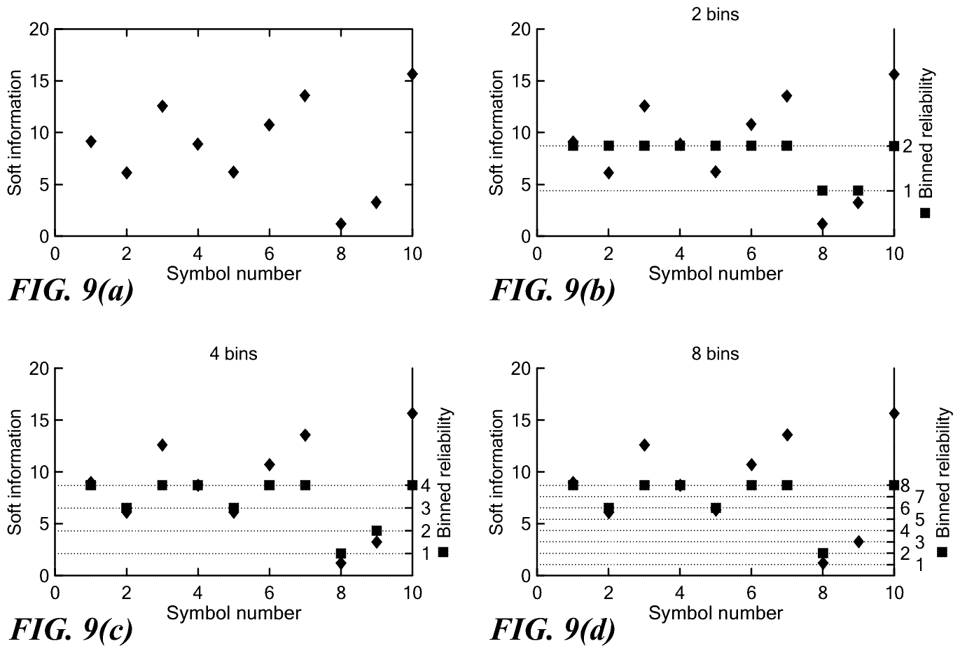

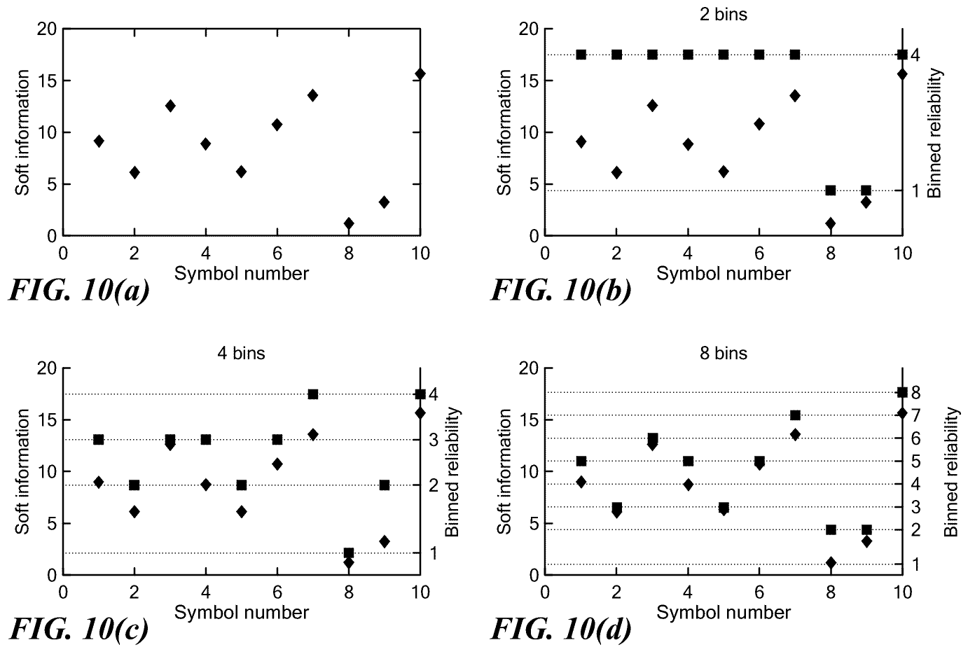

In contrast to the above techniques, DSGRAND envisages a quantization of the real-valued reliabilities, L (Y), into a restricted number of categories determined by a quantization level as shown in FIGS. 9 and 10. Before treating the limitation of the upper-bound, consider the following unbounded quantization of reliability parametrized by β>0 starting from the origin

$$R ( Y ) = β ⌈ \frac{L ( Y )}{β} ⌉ .$$

For a given block of n bits and corresponding discretized reliabilities, let s(i,q)=1 if R(Yᵢ)=βq and zero otherwise, let m_{q}=∈ᵢ₌₁ⁿs(i,q) be the number of bits in quantization level q, and let z^{n,q} denote the subset of the string zⁿ such that s(i,q)=1. With this quantized approximation, one embodiment of DSGRAND's query order follows

$${\sum }_{i = 1}^{n} R ( {Y}_{i} ) {z}_{i} = β {\sum }_{q \geq 1} {qw}_{H} ( {z}^{n , q} ) ∝ {\sum }_{q \geq 1} {qw}_{H} ( {z}^{n , q} )$$

in increasing order. That is, the query order would follow a weighted sum of Hamming weights of bit flips corresponding to indices in each discretized level.

Given log₂(Q) bits of soft information per bit, DSGRAND creates a quantization of the real valued reliabilities, L(Yᵢ), into the first Q−1 categories, with the final category covering β[Q−1, ∞) and being assigned R(Y)=Q. Thus for a received block of symbols with m^{Q}=(m₁, . . . ,m_{Q}) bits in each quantization level and a total Hamming weight W, we wish to identify the set of noise effect sequences (sometimes called herein a “bin”)

$$\{ {z}^{n} : {\sum }_{q = 1}^{Q} {qw}_{H} ( {z}^{n , q} ) = W , {w}_{H} ( {z}^{n , q} ) \leq {m}_{q} ∀ q \} .$$

Defining w^{Q}=(w₁, w₂, . . . , w_{Q}), with each w_{q} representing the number of bits in the corresponding quantization level q to be flipped for the given sequence weight W, and setting

$$ω ( W , {m}^{Q} ) = \{ {w}^{Q} : {\sum }_{q = 1}^{Q} {qw}_{q} = W , {w}_{q} \leq {m}_{q} ∀ q \}$$

to be all viable combinations of weights w_{q} that give the desired overall weight W, the above set of noise effect sequences in the bin of weight W can be identified with

$${⋃}_{{w}^{Q} εω ( W , {m}^{Q} )} \{ {w}_{H} ( {z}^{n , 1} ) = {w}_{1} \} \times … \times \{ {w}_{H} ( {z}^{n , Q} ) = {w}_{Q} \} ,$$

where the product is Cartesian.

With a total weight W=0, one has ω(0,m^{Q})=(0, . . . ,0) and the most likely noise effect is no bit flips. With W=1, one computes ω(1,m^{Q})=(1, . . . ,0) so all noise effect sequences that have any one bit with s(i,1)=1, flipped are binned together. With an overall weight of W=2, if m₁≥2, ω(2,m^{Q}) consists of two vectors, (2,0, . . . ,0) and (0,1,0 . . . ,0) so that any sequence with two bits, say i and j, with s(i,1)=1 and s(j,1)=1 flipped or any sequence with one s(i,2)=1 bit flipped would be binned together, and so on.

In practice, identifying the set ω(W,m_{Q}) amounts to an integer partition problem that can be solved efficiently. For a given w^{Q}∈ω(W,m^{Q}), generating all noise effect sequences

$$\{ {z}^{n} : {w}_{H} ( {z}^{n , 1} ) = {w}_{1} \} \times … \times \{ {w}_{H} ( {z}^{n , Q} ) = {w}_{Q} \}$$

can be achieved using minor modifications to the circuits developed for hard-detection GRAND-BSC algorithms. As a result, DSGRAND is well suited to implementation in hardware.

For simulated performance evaluation, we assume binary phase-shift keying (BPSK) modulation and additive white Gaussian (AWGN) with variance σ². From the discussion above, we have that L(Y)=2|Y|σ², and we elect to quantize into bins with parameter

$$β = \frac{2}{{σ}^{2}} \frac{1 - σ / 2}{Q} .$$

The first term, 2/σ², normalizes for the increase in reliability with SNR, while the second term, (1−σ/2)/Q, ensures that approximately 30% of the least reliable bits are accurately quantized, while the 70% most reliable bits are grouped together. For comparison with DSGRAND at distinct levels of quantization, we use GRAND as a ML hard detection decoder and ORBGRAND as the state-of-the-art universal soft detection decoder.

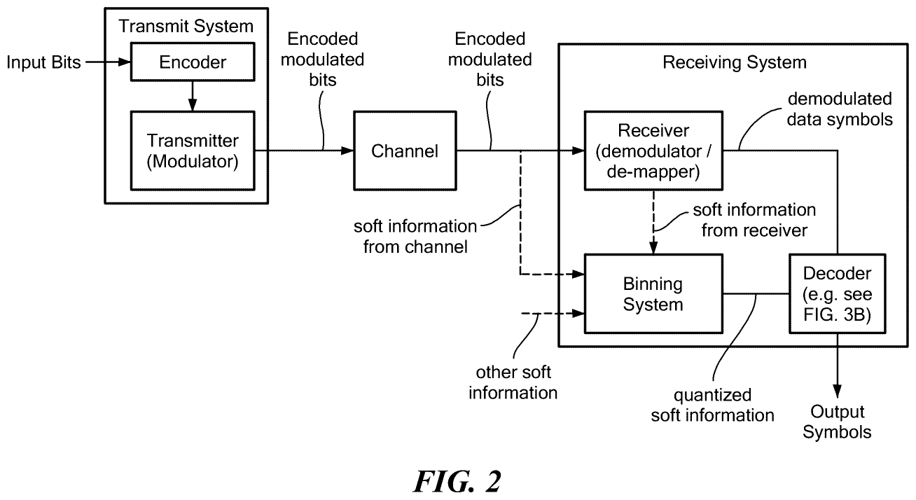

Referring now to FIG. 2, a communication system includes a transmit system having an encoder configured to receive and encode a stream of digital bits.

The encoded digital bit stream (or more simply “encoded bit stream”) is provided to a transmitter which receives and modulates the encoded bit stream for transmission over a channel as is generally known. It should be appreciated that any encoding and/or modulation schemes (including any combination or encoding and modulation) may be used (e.g. any linear or nonlinear modulation scheme may be used).

The channel may be implemented as a wired channel (e.g. comprising one or more of twisted-pair wire, coaxial cable, and fiber-optic cable) and/or a wireless channel (e.g., utilizing transmission of radio frequency signals, microwave signals, satellite signals, acoustic signals, or infrared signals). Multiple encoded bit streams may be multiplexed over the channel as is generally known.

The encoded modulated bit stream propagates through the channel and is received in whole or in part by a receiving system. The receiving system includes a receiver configured to receive and demodulate the encoded modulated bit stream signal provide thereto. The receiver may include a demodulator/de-mapper that converts received, raw channel data to encoded data symbols (e.g. encoded via QAM or other technique) that may be bits, and provides demodulated data symbols to a decoder operating in accordance with noise effect guessing techniques. As such, the decoder may decode any strings of symbols provided thereto regardless of the technique used to encode the symbols. Thus, the decoder acts as a universal decoder (i.e. a decoder capable of decoding any encoded data symbols).

The receiving system further includes a binning system. The binning system receives and processes soft information on noise effect provided thereto. The soft information on noise effect may be per-symbol soft information (i.e., soft information related to a particular symbol). The soft information on noise effect may be provided to the binning system from one or more sources. For example, the binning system may receive quantized soft information from the channel (i.e., directly from the channel) and/or from the demodulator/de-mapper and/or from any other sources. The binning system processes the soft information on noise effect provided thereto for a sequence of symbols and provides binned putative sequences of noise effects to the decoder. Examples of the manner in which the binning system processes the soft information will be described in detail hereinbelow. In general, however, the soft information on noise effect associated with a symbol can be used to create a set of quantized weights for the noise effects that may affect that symbol. Sequences of noise effects, where each noise effect in the sequence is selected from the set of possible noise effects for the corresponding symbol, are binned in such a way that all strings of noise effects in a bin have an equal or similar total weight, where the total weight is as a function of the quantized soft information of the noise effects for the symbols in the sequence of strings.

The design of the bins is related to the soft information quantization as described herein. In general overview, however, once a quantization is selected it is fixed and it is possible to have scenarios where different binning with the same quantized soft information is developed.

The decoder receives the quantized soft information and creates the corresponding binning of putative noise effect sequences. The decoder decodes the encoded bits provided thereto using a noise guessing technique based on the binning of sequences of putative noise effect sequences.

It should be appreciated that the various embodiments of binning systems and decoders described herein may be implemented in one or more processors and/or the functionality performed by the binning system and decoder may be in the same processor or distributed across multiple processors. After reading the disclosure provided herein, one of ordinary skill in the art will appreciate how to implement the systems and techniques described herein in practical circuits and devices.

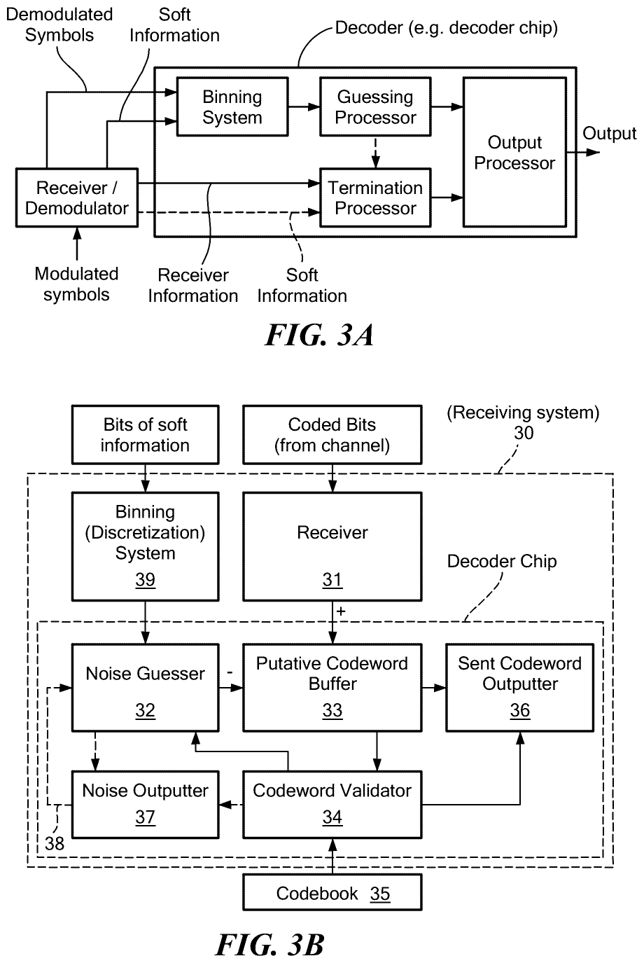

Referring now to FIG. 3A, a receiver is configured to receive and demodulate (de-map) a modulated, encoded sequence of symbols affected by channel noise. The receiver may be the same as or similar to the receiver described above in conjunction with FIG. 2 (as noted above in conjunction with FIG. 2, the receiver may act as a demodulator/de-mapper). The receiver provides demodulated symbols and soft information to a decoder.

The decoder operates in accordance with noise guessing techniques and also utilizes soft information provided thereto. The decoder may decode any symbols provided thereto regardless of the technique used to encode the bits.

In this example embodiment, the decoder includes a binning system which receives and processes the demodulated symbols and quantized soft information provided thereto. The binning system may be the same as or similar to the binning system described above in conjunction with FIG. 2. As noted above, the soft information may be per-symbol soft information (i.e., soft information related to a particular symbol), and binning is performed on sequences of symbols. In general, soft information associated with a symbol can be used to generate a quantized set of possible noise effects for that symbol. That is, symbol effects are assigned quantized weights related to soft information associate with the respective symbol.

The decoder provides quantized noise effects and associated symbols to a guessing processor which operates in accordance with a noise guessing technique which uses the quantized noise effects to generate a binning of putative noise effect sequences on associated symbol sequences, Using the bins to order the guessing, the guessing processor provides symbols to an output processor.

The receiver may also provide channel information (e.g. signal-to-noise ratio) and optionally symbol-specific soft information on noise realization to a termination processor. In embodiments, the termination processor may determine a termination condition based upon received information. In general, the termination processor provides information to the output processor which indicates to the output processor that a termination (or stopping) condition exists.

As indicated in the example embodiment of FIG. 3A, the termination processor may determine a termination condition based upon information from a receiver and/or based upon soft information. In the example embodiment of FIG. 3A, soft information is illustrated as being provided to the termination processor from the receiver. However, after reading the disclosure provided herein, one of ordinary skill in the art will appreciate the soft information may be provided to the termination processor from a source other than the receiver. For example, the soft information may be provided to the termination processor from the binning system or directly from the channel or from the guessing processor (as indicated by the dashed line in FIG. 3A) or the termination processor may receive the soft information by some other means.

In embodiments, the termination processor may determine a termination condition based upon one or more of: a receiver SNR exceeding a threshold SNR; a repetition count reaching a threshold value; a determination that a codebook rate is greater than capacity due to a temporary decrease in channel capacity (e.g. as caused by transient noise); and/or a codeword validator declaring an erasure for a code); based upon the guessing processor providing a first codeword; based upon the guessing processor providing a predetermined number of codewords; when a predetermined number of guesses is reached; after reaching a number of guesses that is determined according to SNR; when some total number of guesses is reached; when a time limit has been reached; a likelihood that a correct symbol has been found (i.e. a likelihood of correctness or a probability of correct decoding has been reached); a likelihood that a correct symbol has been found exceeding a threshold likelihood value; the existence of a set of codewords all having a probability of correctness greater than some threshold probability value PLIST. In embodiments, the termination processor may determine a termination condition based upon soft information. In embodiments, the termination processor may determine a termination condition based upon a combination of receiver information and soft information. In embodiments, the use of soft information may be optional (as indicated by the dashed soft information line leading to the termination processor in FIG. 3A). The termination processor receives and processes the information provided thereto and provides an output signal (e.g., related to one or more termination conditions) to the output processor.

The output processor may operate in a variety of different manners according the needs of a particular application. In one example embodiment, the output processor receives de-coded symbols from the guessing processor and a termination condition from the termination processor and in response thereto the output processor provides an output. The output may correspond, for example: a fixed size list of de-coded symbols; a list of list of symbols according to probabilities; a decision to abandon the decoding process for one or more symbols. The output processor may process the information provided thereto parallel or in series.

It should be appreciated the guessing processor, termination processor and output processors (and any of the processors described herein) may comprise more one processors (or processing devices) and the functions of the guessing, termination and output processors may be distributed among one or more processors or processing devices.

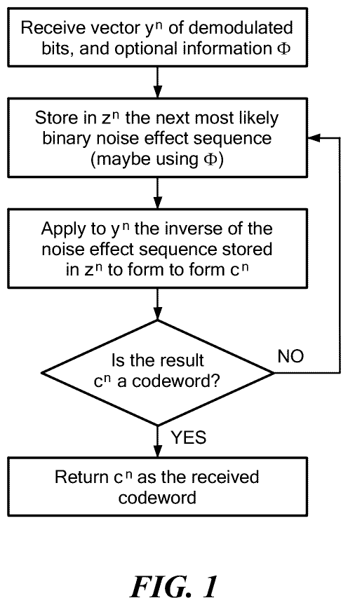

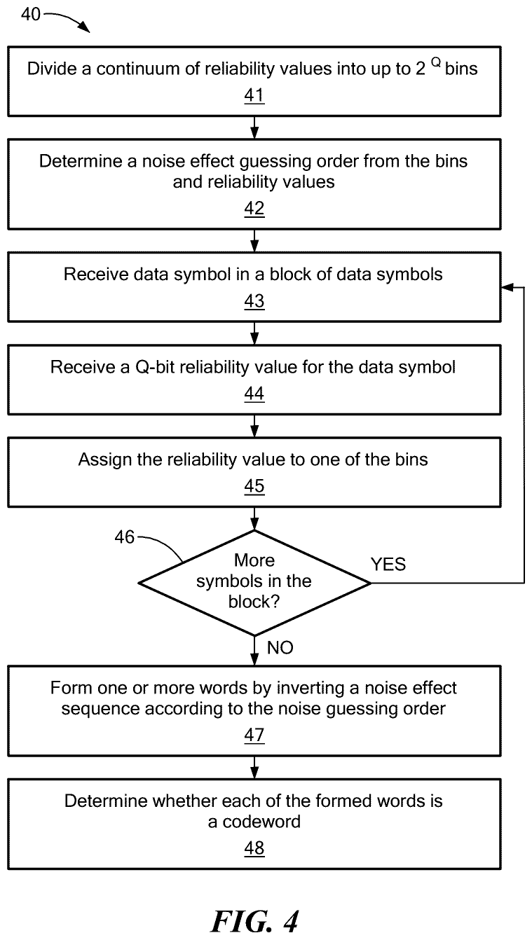

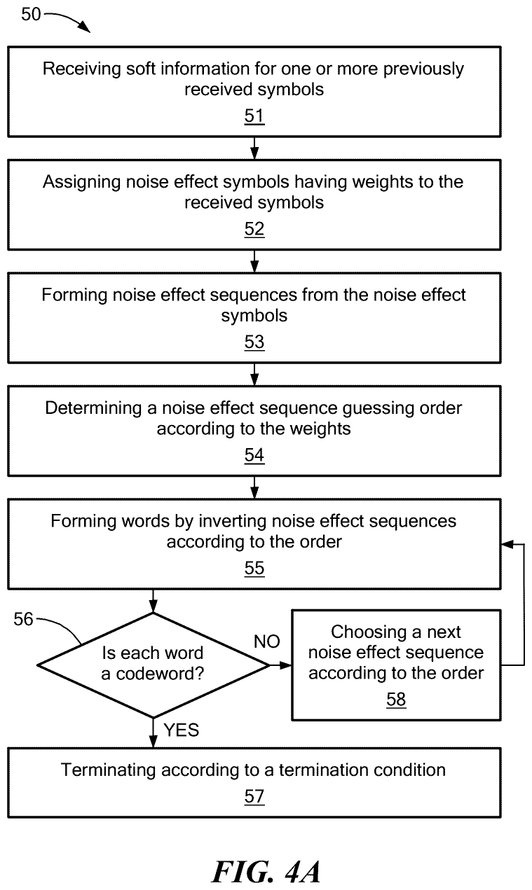

Referring now to FIG. 3B, an example device 30 which may, for example, be the same as or similar to a receiving system described above in conjunction with FIG. 2 includes functional components that implement the processes shown in the algorithm of FIG. 1, as improved by the processes shown in FIG. 4 and described below.

The device 30 includes a receiver 31 for receiving channel output blocks from a data channel. The receiver 31 may be, for example, a network interface card (NIC) described below, or similar means. The receiver 31 may, in some embodiments, be configured to receive data from the data channel as data blocks.

The device 30 includes a noise guesser 32 for iteratively guessing noise effect sequences. The noise guesser 32 may be implemented, for example, using a CPU and primary storage, a custom integrated circuit, or similar means.

The device 30 includes a putative codeword buffer 33 for transiently storing putative codewords (i.e. sequences of symbols input to the channel). The putative codeword buffer 33 may be, for example, primary storage, a volatile memory, or similar means. Thus, the putative codeword buffer 33 stores a channel output block that stores a sequence of symbols demodulated by the receiver 31. The putative codeword buffer 33 is also used to store the channel output block after using a guessed noise effect sequence (i.e. a sequence of noise effect symbols) received from the noise guesser 32 to reverse a putative noise effect, as indicated in FIG. 3B. In what follows, the block of received symbols with its noise effect reversed is called a “word”, to distinguish it from the received block without its noise effect reversed.

The device 30 includes a codeword validator 34 for validating words. The codeword validator 34 may be implemented, for example, using a CPU and primary storage, a custom integrated circuit, or similar means. Thus, if the codeword validator 34 determines that the word stored in the putative codeword buffer 33 is a valid codeword, it may transmit a “success” signal to the noise guesser 32, and a sent codeword outputter 36 and noise outputter 37 described below. If not, the codeword validator 34 may transmit a “continue” signal to the noise guesser 32 that it should guess a next most likely sequence of noise symbols.

In some embodiments, the codeword validator 34 may determine that the device 30 should cease further attempting to guess noise effect sequences. If so, it may transmit a “failure” signal to the noise guesser 32, the sent codeword outputter 36, and the noise outputter 37.

The device 30 may include an optional codebook 35 for use by the codeword validator 34. The codebook 35 may be implemented, for example, using primary storage, a volatile or non-volatile or programmable memory, or similar means. In some embodiments, the codeword validator 34 uses the codebook 35 to determine whether the word stored in the putative codeword buffer 33 is a valid codeword. If so, the codeword validator 34 transmits the “success” signal described above. In other embodiments, the optional codebook 35 is absent, and the codeword validator 34 performs a computational validation to determine whether the word stored in the putative codeword buffer 33 is valid. If so, the codeword validator 34 generates the “success” signal described above.

The device 30 includes a sent codeword outputter 36 for outputting channel input codewords sent by the data sender, as determined by the codeword validator 34. The sent codeword outputter 36 may be any coupling to another circuit or device (not shown) that performs further processing on the channel input codeword, as determined by the device 30. Thus, the sent codeword outputter 36 outputs the word stored in the putative codeword buffer 33 upon receiving a “success” signal from the codeword validator 34.

In some embodiments, the sent codeword outputter 36 performs the error handling process 27. Thus, upon receiving a “failure” signal from the codeword validator 34, the sent codeword outputter 36 indicates the failure to the coupled circuit. Failure may be indicated, for example, by producing a high- or low-voltage error signal on the coupled circuit. Alternately or in addition, the sent codeword outputter 36 may transmit an erasure (e.g. a block of all zeroes or all ones), or “soft” information about the error to the coupled circuit to permit the coupled circuit to diagnose the error. Such soft information may include, for example, a count of how many tries to decode had been performed, or data indicating an ordering of the noise effect sequences.

The device 30 includes a noise outputter 37 for outputting channel noise effect sequences, as determined by the codeword validator 34. The noise outputter 37 may be any coupling to another circuit or device (not shown) that performs further processing on the guessed sequence of noise effects. The noise outputter 37 outputs the guessed sequence of noise effects upon receiving a “success” signal from the codeword validator 34.

The noise guesser 32 optionally includes a function for analyzing noise effect sequences, as indicated by the dashed line 38 from the noise outputter 37 to the noise guesser 32. Thus, in addition to outputting the guessed sequence of noise symbols to any coupled circuit, the noise outputter 37 may output the guessed noise effect sequence to the noise guesser 32. The noise guesser 32, in turn, may analyze the guessed noise effect sequence, for example using machine learning, to learn patterns of the channel noise. The noise guesser 32 may then use these noise patterns to update its noise model and reorder the noise effect sequences. Such reordering may be accomplished, for example, in accordance with a likelihood order (e.g. a maximum likelihood order), and may be made using an estimation technique or a direct calculation technique. In some embodiments, the analysis includes training, where known input blocks are used to train the receiver on channel noise. Alternately or in addition, the analysis may include includes extrinsic information, such as feedback from the sender or from other decoders, to enable on-the-fly machine learning. The analysis, or a portion thereof, may be performed by a circuit coupled to the noise outputter 37, and the reordered noise effect guesses may be fed back into the noise guesser 32. Such a design advantageously simplifies the design of the noise guesser 32.

The device 30 further includes a binning (or discretization or quantization) system 39. The binning system 39 may be implemented, for example, using an application-specific integrated circuit (ASIC), field-programmable gate array (FPGA), or similar device. In one embodiment, the binning system 39 is programmed, based on the number of bits Q of soft information that are associated with each data symbol received from the channel, to divide a continuum of reliability values into up to 2° reliability levels, and to assign each noise effect associated with the received data symbol to one of the reliability levels according to soft information that is associated with the symbol, as shown in connection with FIGS. 9 and 10 and described below. In some embodiments, assigning each noise effect associated with a received symbol to one of the up to 2° reliability levels includes discretizing a reliability value for the received data symbol.

Moreover, the noise effect guesser 32 is configured to determine a noise effect guessing order according to the reliability levels provided by the binning system 39. In particular, in some embodiments, determining the noise effect guessing order includes ordering sequences of noise effects by increasing reliability values, each reliability value corresponding to a weight associated with a bin, where the weights of all noise effect sequences in a bin are equal or similar to the weight of the bin, and where the weight of a noise effect sequence is derived from the quantized soft information associated with the noise effects of the symbols in the corresponding sequence. In some embodiments, assigning noise effect sequences to a bin is determined by solving the integer partition problem for the total weight associated with that bin.

In the embodiment disclosed above, the quantization is done by a quantization system outside of the decoder, to reduce the amount of data transported internally in the decoder. However, it is also contemplated to perform quantization in some embodiments in the decoder, rather than as a separate function within the device.

It should be appreciated that in various embodiments, quantization is performed on a symbol-by-symbol basis, while determining noise effect sequences is performed on a block-by-block basis.

FIG. 4 is a flowchart of a method 40 of decoding a plurality of received symbols according to an embodiment. The method shown in FIG. 4 may be performed illustratively by the communications system shown in FIG. 2, and in particular by the receiving system, or by the device 30 shown in FIGS. 3A, 3B.

The method 40 includes, prior to receiving the symbols, two processes. The first process 41 divides a continuum of reliability values into at most 2^{Q} reliability levels, according to the techniques described above. It is appreciated that possession of Q bits of soft information permits dividing the continuum of reliability values into at most 2^{Q} levels, but fewer levels may be used.

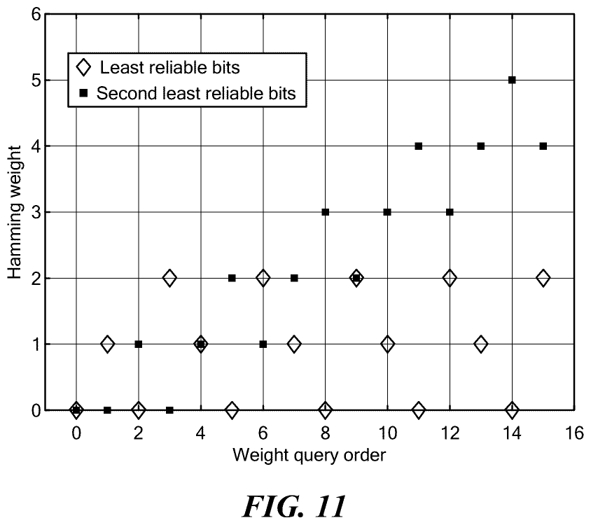

The second process 42 determines a noise effect guessing order according to the reliability levels. One such noise effect guessing order is illustratively shown in FIG. 11 and described below.

The method 40 next includes a process 43 for receiving a data symbol (e.g. a bit, or a point in a constellation such as QAM) in a block of data symbols. In some embodiments, the process 43 receives the data symbol into the receiver 31.

Either concurrently or at a later time, the method 40 includes a process 44 for receiving a Q-bit reliability value for the data symbol, i.e. as soft information relating to the data symbol. In some embodiments, the process 44 receives the reliability value into the quantization processor 39. For example, if the data symbol is meant to represent a point in a constellation, the reliability value may indicate a distance from the symbol to the nearest point in the constellation. Alternately, the reliability value may indicate a signal-to-noise ratio (SNR) of the channel at the time that the symbol was transmitted. It is appreciated that other soft information may be included in the Q-bit reliability value, as known in the art. If the soft information is received at a later time, the method 40 applies a mechanism for associating the received soft information with its corresponding data symbol, e.g. through the use of timestamps or other techniques known in the art.

The method 40 further includes a process 45 for assigning the reliability value to one of the 2^{Q} levels. The assignment may be performed by the quantization processor 39, or by the noise guesser 32, or by some electronic circuitry for that purpose. Assignment of reliability values to levels is shown in FIGS. 9 and 10 and discussed below in more detail.

The method 40 also includes a decision process 46 for determining whether there are more data symbols in the block. The process 46 may be performed by the receiver 31, or the noise guesser 32, or a combination of the two. If there are more symbols to receive, the method 40 returns to process 43.

However, if there are no more symbols to receive, the method 40 continues to a process 47 of forming one or more words by inverting a noise effect sequence on the received block according to the noise effect guessing order determined in process 42. It should be observed that process 44 receives soft information that is associated with each data symbol, while process 47 inverts the noise effect on the entire received block to form a sequence of “words” (i.e. putative codewords). In particular, the soft information is applied at a level of granularity that is finer than that of the received block, while the reversal of the guessed noise effect is applied at the coarser level of granularity of the entire block via binned noise effect sequences.

Thus, to complete the method 40, a process 48 determines whether each of the formed words is a codeword. The process 48 may be performed in some embodiments by a codeword validator 34 using a codebook 35. It is appreciated that the process 47 may form a sequence of words using the most likely (or approximate most likely) order of noise according to the received soft information, determined as described below, and thus that the process 48 produces a sequence of decodings of the received data symbols into codewords in decreasing order of likelihood.

In FIG. 4A is shown a flowchart of a method 50 of decoding received symbols according to an alternate embodiment. The method shown in FIG. 4 may be performed illustratively by the communications system shown in FIG. 2, and in particular by the receiving system, or by the device 30 shown in FIGS. 3A, 3B.

The method 50 includes a first process 51 further receiving, for one or more of the received symbols, up to log₂(Q) bits of associated soft information, where log₂(Q) is an integer.

The method 50 next includes a second process 52 assigning, to each of the one or more of the received symbols, one or more noise effect symbols having a respective weight that is determined by the up to log₂(Q) bits of associated soft information. The weight for each noise effect symbol may be, illustratively, a Hamming weight of the noise effect symbol. In this way, each received symbol may be associated with a list of possible noise effects weighted by relative likelihood.

The method 50 continues with a third process 53 forming noise effect sequences from the noise effect symbols. As described above, each noise effect sequence will have a total weight that equals the summed weights of its noise effect symbols. Thus, the total weight of the noise effect sequence may be viewed as a measure of the proximity of the noise effect sequence to the received signal.

The method 50 next continues with a fourth process 54 determining a noise effect sequence guessing order according to the respective weights. This may be done, as described above, by placing noise effect sequences into bins according to their respective total weights. That is, each bin holds one or more noise effect sequence, and all of the noise effect sequences in each bin have an equal total weight or range of total weights.

The method 50 further continues with a fifth process 55 forming one or more words by inverting a set of sequences of noise effect symbols, on the plurality of received symbols, according to the noise effect sequence guessing order. Thus, noise effect sequences are chosen according to the noise effect sequence guessing order, and putative codewords are formed in the receiver by reversing the effects of the chosen sequences. Note that soft information applies to each received symbol, but the effect of noise is reversed on a block-by-block basis using noise effect sequences.

The method 50 next includes a decision process 56 determining whether each of the formed one or more words is a codeword. Due to the determination of noise effect sequence guessing order using the techniques described herein, it is expected that each of the formed words will be a codeword on the first such determination the majority of the time. In such cases, the method 50 concludes with a process 57 terminating according to a termination condition (e.g. all symbols have been received and correctly decoded).

In case one or more of the formed words is not a codeword, then the entire decoding is considered incorrect, and the method 50 continues to a process 58 choosing a next noise effect sequence according to the noise effect sequence guessing order. In various embodiments as described above, noise effect sequences are guessed according to maximum likelihood (i.e. the most likely noise effect of no bit flips is guessed first, followed by noise effect sequences that have any one bit error, and so on). The method 50 then returns to the process 55 to form a next set of putative codewords. The method continues this way until either all formed words are codewords, or another termination condition is reached (e.g. a fixed number of sets of noise effect sequences has been tried without success). In this case, an erasure may be output.

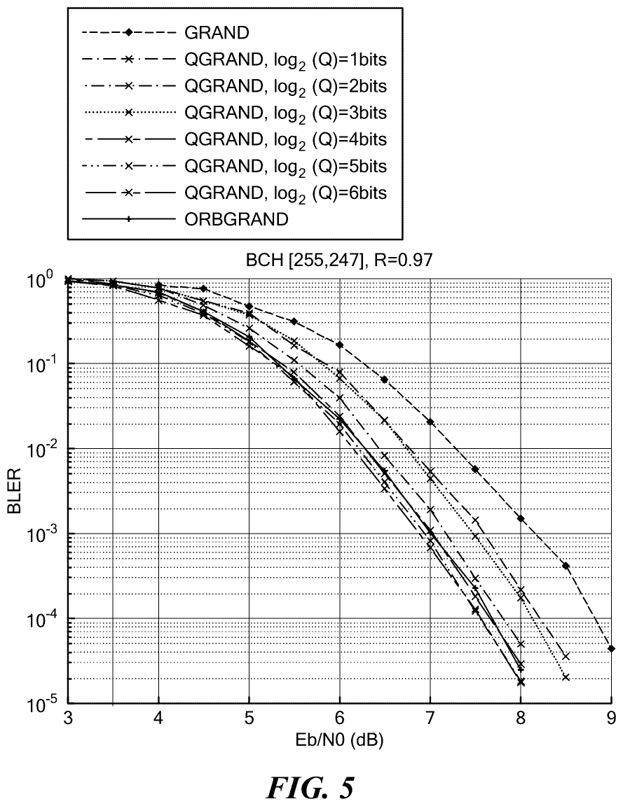

FIG. 5 shows decoding results for a BCH code. BCH codes traditionally only have a hard detection decoder, Berlekamp-Massey, and previous results have shown that hard detection GRAND provides identical block error rate performance. ORBGRAND, as known in the art, and DSGRAND as disclosed herein, both enable soft detection decoding of BCH codes with comparable performance. ORBGRAND, which provides near soft-detection ML decoding using 8=┌log₂(255)┐ bits of soft information per received bit, is seen to have a 1 dB gain over GRAND at a BLER of 10⁻⁴. As the number of quantized soft detection bits, log₂(Q), per demodulated bit increases, DSGRAND is seen to give a gain of 0.6 dB with 1 or 2 bits of soft information, to providing near identical performance to ORBGRAND with 4 bits of soft information, to marginally outperforming ORBGRAND by 0.1 dB but with only 5 or 6 bits of soft detection information per bit.

Embodiments of DSGRAND disclosed herein advantageously allocate received bits into ordered reliability ranges on the basis of soft information, thereby forming groups of bits having similar reliability. By contrast, in ORBGRAND the received bits are individually ordered by their absolute reliability. While the quantization in DSGRAND discretizes the reliability of individual bits, the putative noise effect sequences are queried in increasing order of their weight, which is calculated as a sum of (quantized reliability times the number of bits in that putative noise effect sequence that has that quantized reliability).

We also compare the performance of GRAND algorithms with CA-Polar codes, which will be used for control channel communications in 5G NR. CA-Polar codes are concatenated Polar inner codes with a CRC outer code. In their dedicated decoder, CA-SCL, the Polar bits are used for soft detection list decoding, typically of length 8, and the CRC bits are used to select a decoding from that list. As a comparator, for CA-Polar codes we also show results for the dedicated soft-detection decoder CA-SCL as implemented in the AFF3CT toolbox. As the product of a linear code with a linear code is a linear code, GRAND algorithms use both the CRC and Polar bits of a CA-Polar code for error correction.

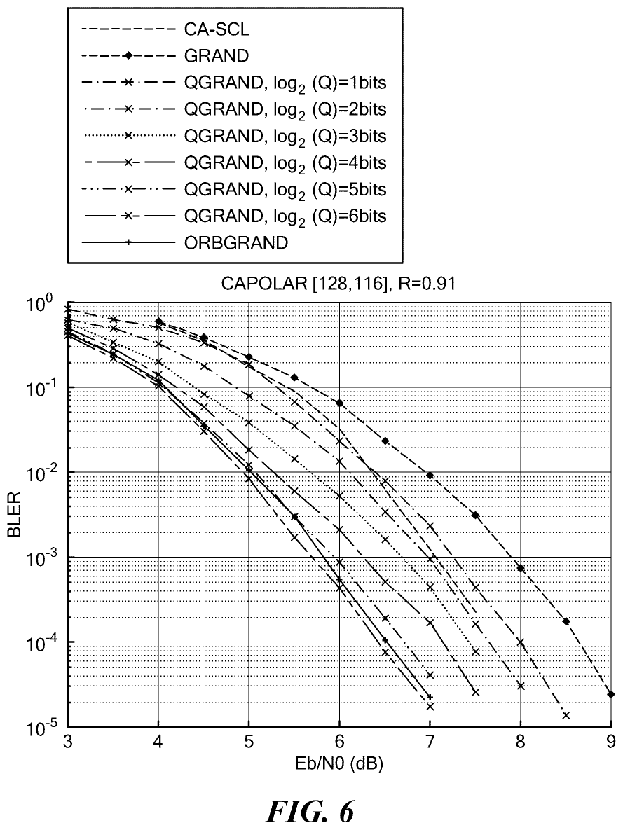

FIG. 6 shows the block error rate (BLER) performance for a CA-Polar[128, 116] code with a rate of 0.91. Again, DSGRAND provides graded improved performance from GRAND to ORBGRAND with increasing levels of quantization. With log₂(Q)=1 bit of soft information per received bit, DSGRAND sees a 0.7 dB gain over GRAND at a block error rate of 10⁻⁴, akin to that reported for SRGRAND. Each additional bit gives, approximately, an additional 0.3 dB gain. ORBGRAND, which uses 7=log₂(128) bits of soft information per received bit, sees a circa 2 dB gain over its hard detection equivalent. With 6 bits of soft information per bit, DSGRAND marginally outperforms ORBGRAND. CA-SCL gives equivalent performance to DSGRAND with 2 bits of soft information per bit, as the error correcting power of the CRC is under-utilized.

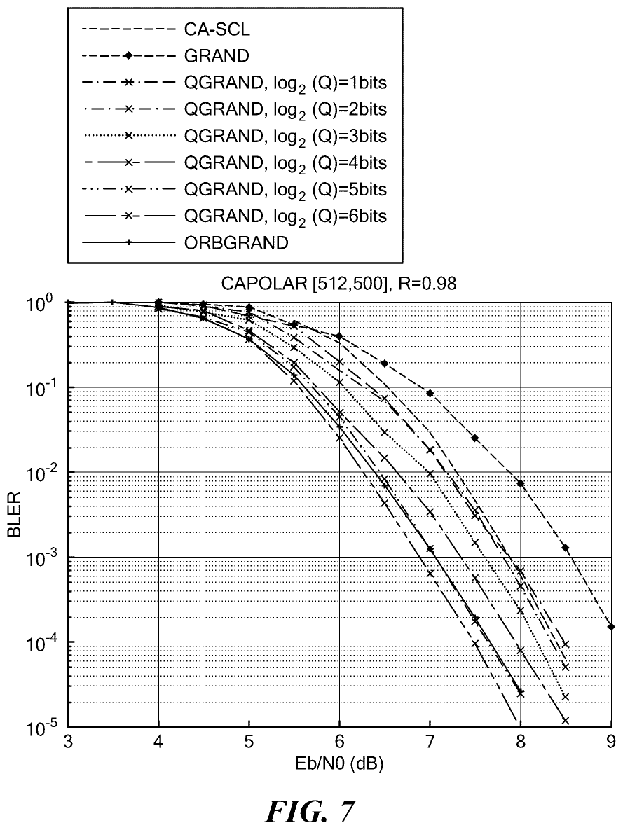

FIG. 7 provides analogous results for a higher rate (0.98), longer CA-Polar [512,500] code. Soft detection decoding enables a 1.5 dB gain over optimal hard detection decoding at a target BLER of 10⁻⁴. DSGRAND sees a graduated improvement in performance from 0.5 dB with 1 bit, to greater than 1.5 dB with 6 bits, again outperforming ORBGRAND and significantly outperforming CA-SCL.

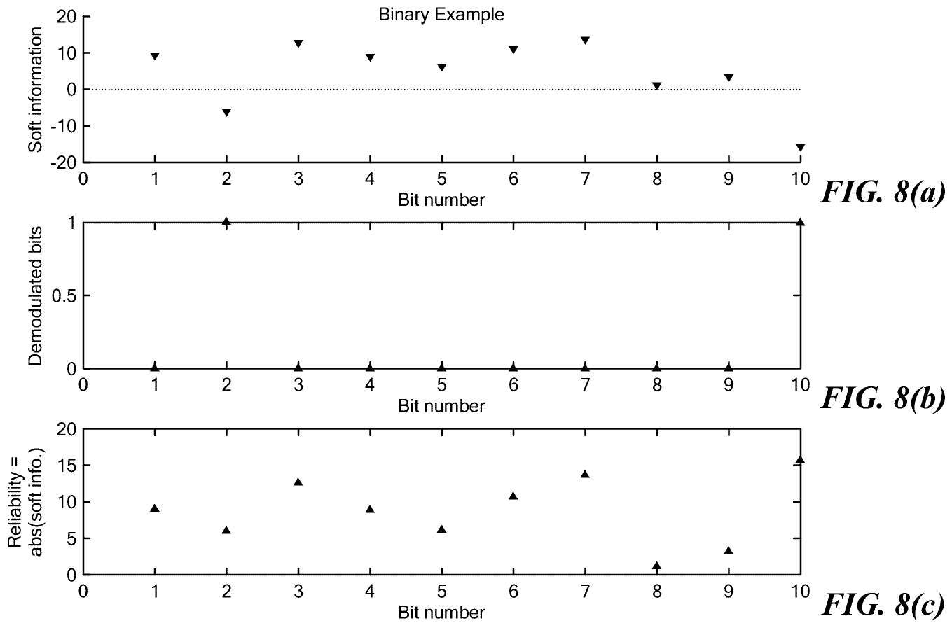

FIGS. 8(a)-8(c) (collectively “FIG. 8”) shows per-bit soft information vs received bit sequence number in an illustrative simulation. In FIG. 8(a), the soft information for the signal Y is shown in raw form as the log-likelihood ratio LLR (Y) defined above, taking on real values (i.e. between-o and +00).

In FIG. 8(b) is shown demodulation of the soft information in FIG. 8(a) into single bits, where the real-valued soft information is demodulated to 0 if the signal is positive and 1 if the signal is negative. That is, if the LLR of a given bit is positive, then it is more likely than not that the bit was a 0 and this is how it is demodulated, while if the LLR of the given bit is negative then it is more likely than not that the bit was a 1.

In FIG. 8(c) is shown the absolute value of the real-valued soft information of FIG. 8(a). This absolute value is L(Y) defined above, and is a measure of the reliability of the received bit. In this Figure, higher numbers represent higher reliabilities, as may be appreciated by consulting the formula for the demodulation error rate B(Y) above.

FIG. 9(a) repeats FIG. 8(c) for visual comparison with FIGS. 9(b)-9(d) to emphasize that the real-valued reliability values L(Y), shown as diamonds, are unquantized. By contrast, FIG. 9(b) shows a 1-bit quantization of the reliability values of FIG. 9(a) according to an embodiment of DSGRAND, in which the continuum is discretized into ranges and reliability values that fall into each range are assigned a respective quantization level (i.e. 1 or 2). In accordance with the above discussion, reliabilities below the level 1 threshold are marked as belonging to (i.e. no more reliable than) level 1, and reliabilities below level 2 are marked as belonging to level 2. That is, each reliability value (shown with a diamond) is quantized by adjusting its value to lie on the quantized reliability line directly above it (shown with a square).

Reliabilities above level 2 represent bits whose demodulation may, in some embodiments, be treated as certain and for which noise guessing is not required. Such embodiments may advantageously yield fast demodulation of these bits. However, in alternate embodiments and as shown in FIG. 9(b), noise guessing may be performed on these bits as well, if they are placed with other bits in the quantization level that represents the highest reliability (i.e., quantization level 2 in this Figure). That is, these bits may be placed in the quantization level covering β[Q−1,∞). Concretely, the raw soft information for received bits 1-7 and 10 is quantized as having reliability level 2 (i.e., higher reliability) and for bits 8 and 9 as having reliability level 1 (i.e., lower reliability).

FIG. 9(c) shows a 2-bit quantization of the reliability values of FIG. 9(a) according to an embodiment of DSGRAND, in which the continuum is discretized into ranges and reliability values that fall into each range are assigned a respective quantization level (i.e. 1 through 4). On the same soft information, using 2 bits of quantization provides more information for use by the noise guesser than does using only 1 bit as in FIG. 9(b). Concretely, the soft information for bits 1-7 and 10 now is divided between the higher reliability levels 3 and 4, while the soft information for bits 8 and 9 now is divided between lower reliability levels 1 and 2. Nevertheless, the relationship between the relative reliabilities of the bits remains intact; bit 1 is more reliable than bit 8 under both scenarios, but the latter quantization captures more information about the magnitude of the difference.

FIG. 9(d) shows a 3-bit quantization of the reliability values of FIG. 9(a) according to an embodiment of DSGRAND, in which the continuum is discretized into ranges and reliability values that fall into each range are assigned a respective quantization level (i.e. 1 through 8). It may be appreciated from this Figure that increasing the number of bits of quantization need not always lead to an improvement in captured information for the noise guesser. In particular, while the total number of quantization levels doubled between FIGS. 9(c) and 9(d), the number of quantization levels in which different bits were placed did not increase: each Figure places bits in four different quantization levels. As will be understood from the discussion below of FIG. 11, noise guessing in DSGRAND depends on the number of different levels into which bits were placed, not necessarily the relative magnitude of the reliability of those bits. Thus, FIGS. 9(c) and 9(d) would be decoded using the same noise effect guessing order.

It is appreciated that the thresholds for reliability that define the quantization levels need not be chosen to be uniformly spaced, as they are shown in FIGS. 9(b)-9(d). Rather, it is important only that these thresholds are chosen to be a multiple of a base reliability value. This broader view of quantization levels is shown in FIGS. 10(a)-10(d) (collectively, “FIG. 10”). FIG. 10(a) repeats FIG. 9(a) for visual comparison with FIGS. 10(b)-10(d).

FIG. 10(b) shows a 1-bit quantization of the reliability values of FIG. 10(a) according to an embodiment of DSGRAND in which reliability thresholds used for quantization are chosen so that each range has a width that is a multiple of a base reliability value. That is, the first or base reliability value (quantization level 1) is just under 5, while the second or higher reliability value is exactly 4 times this number (quantization level 4). Thus, 1-bit quantization as used herein simply means that two quantization levels are chosen.

FIG. 10(c) shows a 2-bit quantization of the reliability values of FIG. 10(a) according to an embodiment of DSGRAND in which reliability thresholds used for quantization are chosen so that each range has a width that is a multiple of a base reliability value. The four quantization levels are at 1×, 4×, 6×, and 8× the base reliability value, as shown. Likewise, FIG. 10(d) shows a 3-bit quantization of the reliability values of FIG. 10(a) according to an embodiment of DSGRAND with eight quantization levels from 1× up to 16× the base reliability value.

Once the soft information has been quantized, noise effect guessing proceeds as now described. FIG. 11 shows Hamming weights of guessed noise vs position in the noise effect guessing order for a sequence of 16 sequences of noise effect guesses in an embodiment of DSGRAND having 1-bit quantization (i.e. two ranges of per-bit reliability), e.g. as shown in FIG. 9(b) or FIG. 10(b). Noise effect guessing proceeds according to increasing error weight, as described above, with weight 0 representing no noise error.

Weight 1 represents 1 bit in the least reliable quantization level (i.e. level 1) and 0 bits in the second least reliability bit (i.e. level 2); as a formula, 1=1*1+0*2. Weight 2 represents 0 bits in level 1 and 1 bit in level 2; that is, 2=0*1+1*2. Weight 3 represents 1 bit in level 1 and 1 bit in level 2; that is, 3=1*1+1*2. Higher weights are distributed similarly.

It should be appreciated that the distribution in FIGS. 9(b) and 10(b) is two bits in level 1 and eight bits in level 2. Therefore, the integer partitions given by the above formulas may have a coefficient representing only 0, 1, or 2 bits for the first term (i.e. the term multiplied by the quantization level 1), and may have a coefficient representing up to 8 bits for the second term (i.e. the term multiplied by the quantization level 2).

Noise effect guessing proceeds first by selecting more bits having a lower reliability level, as these bits are more likely to be in error than bits having a higher reliability level. Thus, the noise guess labeled 0 in FIG. 11 is “no error”: no bits from either level 1 or level 2. Guess 1 is “one bit of error, taken from level 1”. Guess 2 is “one bit of error, taken from level 2”. Guess 3 is “two bits of error, both taken from level 1”. Guess 4 is “two bits of error, one from level 1 and one from level 2”. Guess 5 is “two bits of error, both from level 2”. Guesses 6-8 represent three bit errors, guesses 9-11 represent four bit errors, and so on.

It is appreciated that DSGRAND advantageously permits arbitrary numbers of bits in each received block to be placed in each quantization level of noise effect, and that therefore the noise effect sequence levels and associated noise effect sequence guessing patterns for the received block will change if different numbers of bits land in different quantization levels. It is further appreciated that the example of FIG. 11 applies to 1-bit quantization, and that if higher numbers of bits are used (e.g. as shown in FIG. 9(c), 9(d), 10(c), or 10(d)) then the noise effect sequence guessing pattern will be altered further.

In illustrative implementations of the concepts described herein, one or more computers (e.g., integrated circuits, microcontrollers, controllers, microprocessors, processors, field-programmable-gate arrays, personal computers, onboard computers, remote computers, servers, network hosts, or client computers) may be programmed and specially adapted: (1) to perform any computation, calculation, program or algorithm described or implied above; (2) to receive signals indicative of human input; (3) to output signals for controlling transducers for outputting information in human perceivable format; (4) to process data, to perform computations, to execute any algorithm or software, and (5) to control the read or write of data to and from memory devices. The one or more computers may be connected to each other or to other components in the system either: (a) wirelessly, (b) by wired or fiber optic connection, or (c) by any combination of wired, fiber optic or wireless connections.

In illustrative implementations of the concepts described herein, one or more computers may be programmed to perform any and all computations, calculations, programs and algorithms described or implied above, and any and all functions described in the immediately preceding paragraph. Likewise, in illustrative implementations of the concepts described herein, one or more non-transitory, machine-accessible media may have instructions encoded thereon for one or more computers to perform any and all computations, calculations, programs and algorithms described or implied above, and any and all functions described in the immediately preceding paragraph.

For example, in some cases: (a) a machine-accessible medium may have instructions encoded thereon that specify steps in a software program; and (b) the computer may access the instructions encoded on the machine-accessible medium, in order to determine steps to execute in the software program. In illustrative implementations, the machine-accessible medium may comprise a tangible non-transitory medium. In some cases, the machine-accessible medium may comprise (a) a memory unit or (b) an auxiliary memory storage device. For example, in some cases, while a program is executing, a control unit in a computer may fetch the next coded instruction from memory.

In some cases, one or more computers are programmed for communication over a network. For example, in some cases, one or more computers are programmed for network communication: (a) in accordance with the Internet Protocol Suite, or (b) in accordance with any other industry standard for communication, including any USB standard, ethernet standard (e.g., IEEE 802.3), token ring standard (e.g., IEEE 802.5), or wireless communication standard, including IEEE 802.11 (Wi-Fi®), IEEE 802.15 (Bluetooth®/Zigbee®), IEEE 802.16, IEEE 802.20, GSM (global system for mobile communications), UMTS (universal mobile telecommunication system), CDMA (code division multiple access, including IS-95, IS-2000, and WCDMA), LTE (long term evolution), or 5G (e.g., ITU IMT-2020).

As used herein, “including” means including without limitation. As used herein, the terms “a” and “an”, when modifying a noun, do not imply that only one of the noun exists. As used herein, unless the context clearly indicates otherwise, “or” means and/or. For example, A or B is true if A is true, or B is true, or both A and B are true. As used herein, “for example”, “for instance”, “e.g.”, and “such as” refer to non-limiting examples that are not exclusive examples. The word “consists” (and variants thereof) are to be give the same meaning as the word “comprises” or “includes” (or variants thereof).

The above description (including any attached drawings and figures) illustrate example implementations of the concepts described herein. However, the concepts described herein may be implemented in other ways. The methods and apparatus which are described above are merely illustrative applications of the principles of the described concepts. Numerous modifications may be made by those skilled in the art without departing from the scope of the invention. Also, the described concepts includes without limitation each combination, sub-combination, and permutation of one or more of the abovementioned implementations, embodiments and features.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal, “top,” “bottom,” and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the specification to modify an element does not by itself connote any priority, precedence, or order of one element over another or the temporal order in which acts of a method are performed, but are used merely as labels to distinguish one element having a certain name from another element having a same name (but for use of the ordinal term) to distinguish the elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter.

Accordingly, although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

We claim:

1. A method of decoding a plurality of received symbols, the method comprising:
further receiving, for one or more of the received symbols, up to log₂(Q) bits of associated soft information, where log₂(Q) is an integer;
assigning, to at least one of the one or more of the received symbols, one or more noise effect symbols having a respective weight that is determined by the up to log₂(Q) bits of associated soft information;
forming noise effect sequences from the noise effect symbols;
determining a noise effect sequence guessing order according to the respective weights;
forming one or more words by inverting a set of sequences of noise effect symbols, on the plurality of received symbols, according to the noise effect sequence guessing order;
determining whether each of the formed one or more words is a codeword; and
terminating according to a termination condition.

2. The method according to claim 1, wherein determining the noise effect sequence guessing order comprises determining a total weight of each noise effect sequence and allocating the noise effect sequences into bins according to their respective total weights.

3. The method according to claim 2, wherein allocating the noise effect sequences into bins comprises allocating noise effect sequences having larger reliability values to bins having smaller total weights.

4. The method according to claim 3, wherein allocating a noise effect sequence into a given bin comprises solving an integer partition problem associated with the total weight of the given bin.

5. The method according to claim 1, further comprising determining, for one or more of the noise effect symbols, one of up to Q reliability levels by discretizing a reliability value for the one or more of the noise effect symbols.

6. The method according to claim 1, wherein the received symbols are binary symbols and each of the one or more of the received symbols has one noise effect symbol.

7. The method according to claim 1, wherein the selection of noise effect symbols in a particular noise effect sequence is determined by a measure of proximity of the noise effect sequence to the received signal.

8. The method according to claim 7, wherein the measure of proximity comprises a Hamming weight.

9. A system for decoding a plurality of received symbols, the system comprising:
a receiver for receiving from a data channel the plurality of received symbols and further receiving, for one or more of the received symbols, up to log₂(Q) bits of associated soft information, where log₂(Q) is an integer;
a discretization system for assigning, to at least one of the one or more of the received symbols, one or more noise effect symbols having a respective weight that is determined by the up to log₂(Q) bits of associated soft information, and for forming noise effect sequences from the noise effect symbols;
a noise guesser for iteratively guessing noise effect sequences according to a noise effect sequence guessing order determined according to the respective weights;
a putative codeword buffer for transiently storing putative codewords formed by inverting a set of sequences of noise effect symbols, on the plurality of received symbols, according to the noise effect sequence guessing order; and
a codeword validator for determining whether each of the formed one or more words is a codeword.

10. The system according to claim 9, wherein the receiver comprises a network interface card.

11. The system according to claim 9, wherein the putative codeword buffer comprises a primary storage or a volatile memory.

12. The system according to claim 9, further comprising a codebook for use by the codeword validator to determine whether the word stored in the putative codeword buffer is a valid codeword.

13. The system according to claim 9, further comprising a noise outputter for outputting channel noise effect sequences, as determined by the codeword validator.

14. The system according to claim 9, wherein the noise guesser is configured to determine the noise effect sequence guessing order by determining a total weight of each noise effect sequence assigned by the discretization system and allocating the noise effect sequences into bins according to their respective total weights.

15. The system according to claim 14, wherein allocating the noise effect sequences into bins comprises allocating noise effect sequences having larger reliability values to bins having smaller total weights.

16. The system according to claim 15, wherein allocating a noise effect sequence into a given bin comprises solving an integer partition problem associated with the total weight of the given bin.

17. The system according to claim 9, wherein the discretization system is configured to determine, for one or more of the noise effect symbols, one of up to Q reliability levels by discretizing a reliability value for the one or more of the noise effect symbols.

18. The system according to claim 9, wherein the receiver is configured to receive the received symbols as binary symbols.

19. The system according to claim 9, wherein the discretization system forms noise effect symbols into a particular noise effect sequence using a measure of proximity of the noise effect sequence to the received signal.

20. The system according to claim 19, wherein the measure of proximity comprises a Hamming weight.
